(19) United States
(12) Patent Application Publication
(10) Pub. No.: US 2008/0247218 A1
(43) Pub. Date: Oct. 9, 2008

(54) DESIGN STRUCTURE FOR IMPLEMENTING IMPROVED WRITE PERFORMANCE FOR PCRAM DEVICES

(75) Inventors: Mark C. H. Lamorey, South Burlington, VT (US); Thomas Nirschl, Essex Junction, VT (US)

Correspondence Address: CANTOR COLBURN LLP-IBM BURLINGTON, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/851,036

(22) Filed: Sep. 6, 2007

Related U.S. Application Data
(63) Continuation-in-part of application No. 11/696,251, filed on Apr. 4, 2007.

(51) Int. Cl. G11C 11/00

(52) U.S. Cl. 365/148; 365/163

(57) ABSTRACT

A design structure embodied in a machine readable medium used in a design process includes a circuit for implementing a write operation for a programmable resistive random access memory array, the circuit including a current source coupled to a bit line associated with a programmable resistive memory element; a dummy path configured for selective coupling to the bit line prior to activation of a word line associated with the memory element, wherein the passage of current through the bit line and dummy path precharges the bit line; and control circuitry for decoupling the dummy path from the bit line and for activating the word line associated with the memory element upon achieving a desired operating point of bit line current and bit line voltage, so as to cause current from the bit line to flow for a period of time selected to program the memory element to one of a low resistance state and a high resistance state.

### CROSS-REFERENCE TO RELATED APPLICATIONS

This non-provisional U.S. Patent Application is a continuation in part of pending U.S. patent application Ser. No. 11/696,251, which was filed Apr. 4, 2007, and is assigned to the present assignee.

### BACKGROUND

The present invention relates generally to integrated circuit memory devices and, more particularly, to a design structure for implementing improved write performance for phase-change random access memory (PCRAM) devices.

Dynamic Random Access Memory (DRAM) integrated circuit arrays have been existence for several years, with their dramatic increase in storage capacity having been achieved through advances in semiconductor fabrication technology and circuit design technology. The considerable advances in these two technologies have also resulted in higher and higher levels of integration that permit dramatic reductions in memory array size and cost, as well as increased process yield.

A DRAM memory cell typically includes, as basic components, an access transistor (switch) and a capacitor for storing a binary data bit in the form of a charge. Typically, a first voltage is stored on the capacitor to represent a logic HIGH or binary “1” value (e.g., V_{DD}), while a second voltage on the storage capacitor represents a logic LOW or binary “0” value (e.g., ground). A basic drawback of a DRAM device is that the charge on the capacitor eventually leaks away and therefore provisions must be made to “refresh” the capacitor charge, otherwise the data bit stored by the memory cell is lost.

The memory cell of a conventional Static Random Access Memory (SRAM), on the other hand, includes, as basic components, an access transistor or transistors and a memory element in the form of two or more integrated circuit devices interconnected to function as a bistable latch. An example of such a bistable latch is a pair of cross-coupled inverters. Bistable latches do not need to be “refreshed,” as in the case of DRAM memory cells, and will reliably store a data bit indefinitely so long as they continue to receive supply voltage. However, such a memory cell requires a larger number of transistors and therefore amount of silicon real estate than a simple DRAM cell, and draws more power than a DRAM cell. Like a DRAM array, an SRAM array is also a form of volatile memory in that the data is lost once power is removed.

Accordingly, efforts continue to identify other types of memory elements that are capable of storing data states, that do not require extensive refreshing, and that are non-volatile in nature. Recent studies have focused on resistive materials that can be programmed to exhibit either high or low stable ohmic states. A programmable resistance element of such material could be programmed (set) to a high resistive state to store, for example, a binary “1” data bit or programmed to a low resistive state to store a binary “0” data bit. The stored data bit could then be retrieved by detecting the magnitude of a readout voltage supplying a current switched through the resistive memory element by an access device, thus indicating the stable resistance state it had previously been programmed to.

Phase Change Random Access Memory (“PCRAM” also referred to as “PRAM”) is an emerging non-volatile memory technology which stores data using phase change materials (such as Ge—Sb—Te (GST) alloys) having a programmable electrical resistance that changes with temperature. Other compositions such as GeSb₄, (including substitution/addition of other elements) are also possible for the phase change materials. Individual phase change elements (PCE) are thus used as the storage cells of a memory device. The state of an individual PCE is programmed through a heating and cooling process which is electrically controlled by passing a current through the PCE (or a discrete heating element in proximity to the PCE) and the resulting ohmic heating that occurs. Depending upon the specific applied temperature and duration of heating applied to the PCE element, the structure is either “set” to a lower resistance crystalline state or “reset” to an amorphous, higher resistance state. Essentially, there is no practical limit to the number of times a PCE element may be programmed from the crystalline state to the amorphous state and vice versa.

The changing of the phase of a PCE typically requires a high temperature (e.g., above 200 to 900° C. depending on material properties), as can be obtained by Joule heating from current flowing through the phase change material or discrete resistor. When the phase change material is heated above its melting temperature to thereafter be quickly cooled, the phase change material becomes amorphous to store a data bit of “1.” Alternatively, when the phase change material is heated above its crystallization temperature and maintained at that temperature for a predetermined time before cooling, the phase change material becomes crystalline to store a data bit of “0.”

More specifically, FIG. 1 is a graph illustrating the exemplary thermal cycling operations of a phase change material used as a PCE storage cell. As is illustrated, a first thermal cycling operation includes a “RESET” pulse for converting the PCE from crystalline to amorphous form, and a second thermal cycling operation includes a “SET” pulse for converting the PCE from amorphous to crystalline form. During the RESET pulse, the temperature of the PCM is raised above its melting temperature (Tₘ), followed by a rapid quench over a short time t₁. As a result of the rapid quench, the disordered arrangement of atoms of the PCM due to the melt is retained. Thus, the PCM is left in an amorphous, high resistive state after the RESET pulse. During the SET pulse, the PCM is annealed at a lower temperature with respect to the melting temperature, and for a longer time t₂ with respect to t₁. This process enables the amorphous form to crystallize into a lower resistive state.

Data is read from a given PCRAM cell by selecting a bit line and a word line for that cell, passing a current through that PCRAM cell, and thereafter distinguishing a “1” from “0” based upon the voltage generated from the variable resistance of the phase change material of the PCRAM cell.

One existing method of writing a PCRAM cell is to activate the corresponding word line of the cell and then apply a voltage or current pulse to the corresponding bit line. Due to the parasitic capacitance of the bit line, the current (and thus power) of the cell is initially lower than intended, leading to a slower heating of the cell. In addition, the total energy deposited in the PCE varies with its location in the array, which could introduce additional fluctuations and lead to a broader cell distribution. Accordingly, it would be desirable to be able to implement an improved writing technique for phase-change random access memory (PCRAM) devices.

### SUMMARY

The foregoing discussed drawbacks and deficiencies of the prior art are overcome or alleviated by a design structure embodied in a machine readable medium used in a design process, the design structure including a circuit for implementing a write operation for a programmable resistive random access memory array, the circuit including a current source coupled to a bit line associated with a programmable resistive memory element; a dummy path configured for selective coupling to the bit line prior to activation of a word line associated with the memory element, wherein the passage of current through the bit line and dummy path precharges the bit line; and control circuitry for decoupling the dummy path from the bit line and for activating the word line associated with the memory element upon achieving a desired operating point of bit line current and bit line voltage, so as to cause current from the bit line to flow for a period of time selected to program the memory element to one of a low resistance state and a high resistance state.

In another embodiment, a design structure embodied in a machine readable medium used in a design process includes a phase change random access memory (PCRAM) array, the array including a plurality of memory cells arranged into rows and columns, each of the memory cells including a phase change element (PCE) and an access transistor associated therewith; a plurality of word lines, with each access transistor coupled to one of the word lines; a plurality of bit lines, with each access transistor configured to electrically couple its associated PCE to one of the bit lines upon word line activation; one or more current sources selectively coupled to the plurality of bit lines; a dummy path associated with each bit line, each dummy path configured for selective coupling to the bit line in a precharging operation prior passage of current through any of the PCEs associated with the bit line; and control circuitry for decoupling each dummy path from the associated bit line and for activating the word line associated with the PCE upon achieving a desired operating point of bit line current and bit line voltage, so as to cause current from the bit line to flow through the PCE for a period of time selected to program the PCE to one of a low resistance crystalline state and a high resistance amorphous state.

### BRIEF DESCRIPTION OF THE DRAWINGS

Referring to the exemplary drawings wherein like elements are numbered alike in the several Figures:

FIG. 1 is a graph illustrating the exemplary thermal cycling operations of a phase change material used as a PCE storage cell;

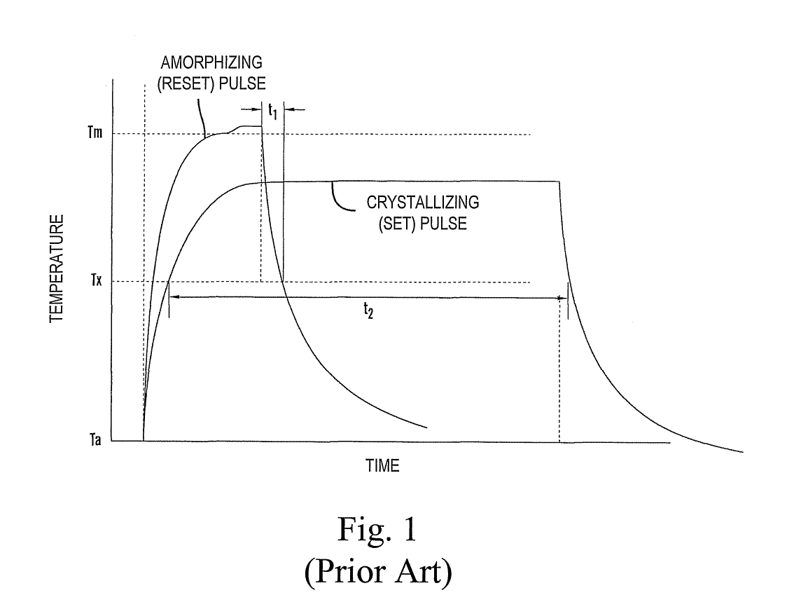

FIG. 2 is a schematic diagram of an exemplary PCRAM array suitable for use in accordance with an embodiment of the invention;

FIG. 3 is a schematic diagram of a bit line precharging device providing a dummy path for current mode precharging, in accordance with an embodiment of the invention;

FIG. 4 is a graph illustrating various precharging current curves for various dummy path resistance values and bias current values;

FIG. 5 is a block diagram of a general purpose computer system which may be used to practice embodiments the invention; and

FIG. 6 is a flow diagram of an exemplary design process used in semiconductor design, manufacturing, and/or test.

### DETAILED DESCRIPTION

Disclosed herein is a design structure for implementing improved write performance for PCRAM devices by minimizing write power variations across an array, as well as across a wide range of PCE and bit line electrical parameters. Briefly stated, a current mode writing source is used to precharge a given bit line through a dummy path just prior to activating the word line coupled to a cell's access transistor and coupling the PCE cell to the bit line. In this manner, the node which defines the PCE's connection to the bit line is already pre-biased close to its operating point prior to allowing programming current through the PCE. Thereby, there is no significant delay in the application of a steady state heating power to the cell. Moreover, the cell is spared from exposure to unnecessary power applications, which may otherwise result in negative effects on the reliability of the devices.

It should be noted that although the exemplary embodiments disclosed herein are described in terms of phase change memory elements, it will be appreciated that they are also applicable to other types of memory devices having memory elements characterized by programmable resistances (e.g., logical low at a first programmed resistance value and logical high at a second programmed resistance value).

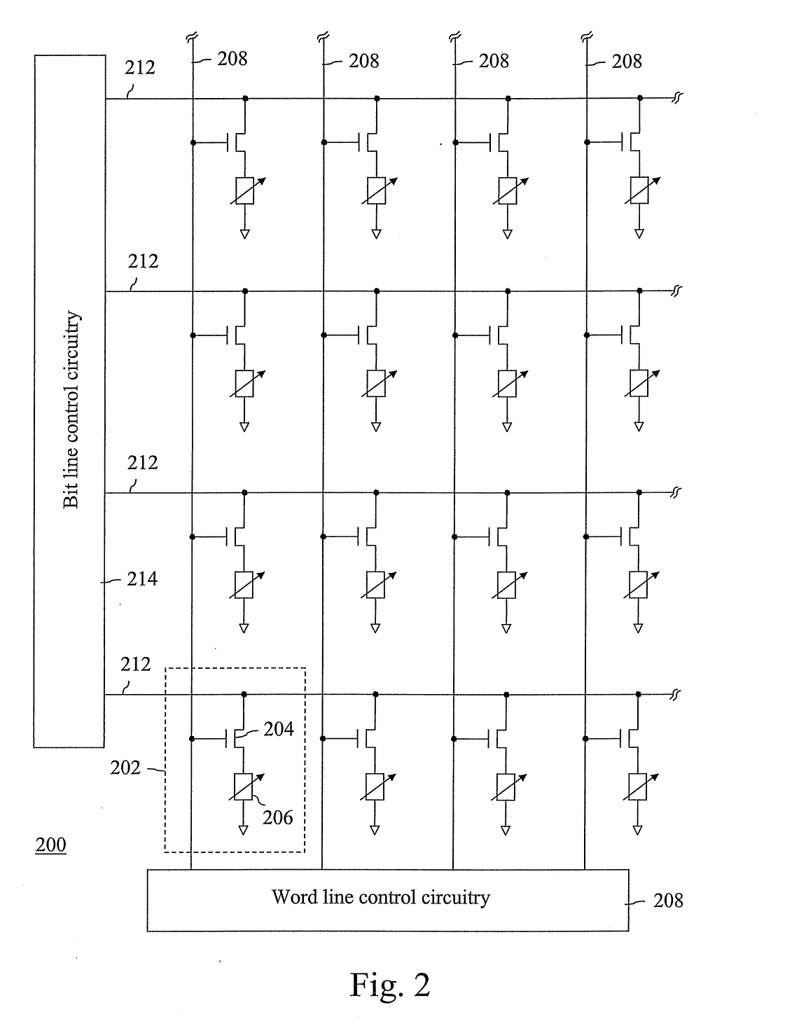

Referring now to FIG. 2, there is shown a schematic diagram of an exemplary PCRAM array 200 suitable for use in accordance with an embodiment of the invention. As is shown, the array 200 includes a plurality of individual memory cells 202, each having an access transistor 204 and a programmable PCE 206 (e.g., such as a GST element described above). The individual cells 202 are arranged into rows and columns, with the gate terminal of each access transistor 204 coupled to one of a plurality of word lines 208 that are coupled to word line control circuitry 210 as known in the art. Further, when activated, each access transistor 204 couples its corresponding PCE 206 to an associated bit (data) line 212, which are coupled to bit line control circuitry 214 (e.g., sense amplifiers, row address decoders, etc.) as also known in the art.

As indicated above, the writing of a PCRAM memory cell (e.g., PCE 206) is typically implemented by heating the PCE 206 through electrical ohmic heating that occurs while passing a current therethrough. Alternatively, a heating current could be passed through an external heater located in close proximity with respect to the PCE. The magnitude of the heating process may be controlled by either a current source or voltage source. The initiation and duration of the heating process may in turn be controlled via the current/voltage source, the word line and/or the bit line. However, each of these conventional control points has drawbacks and advantages associated therewith.

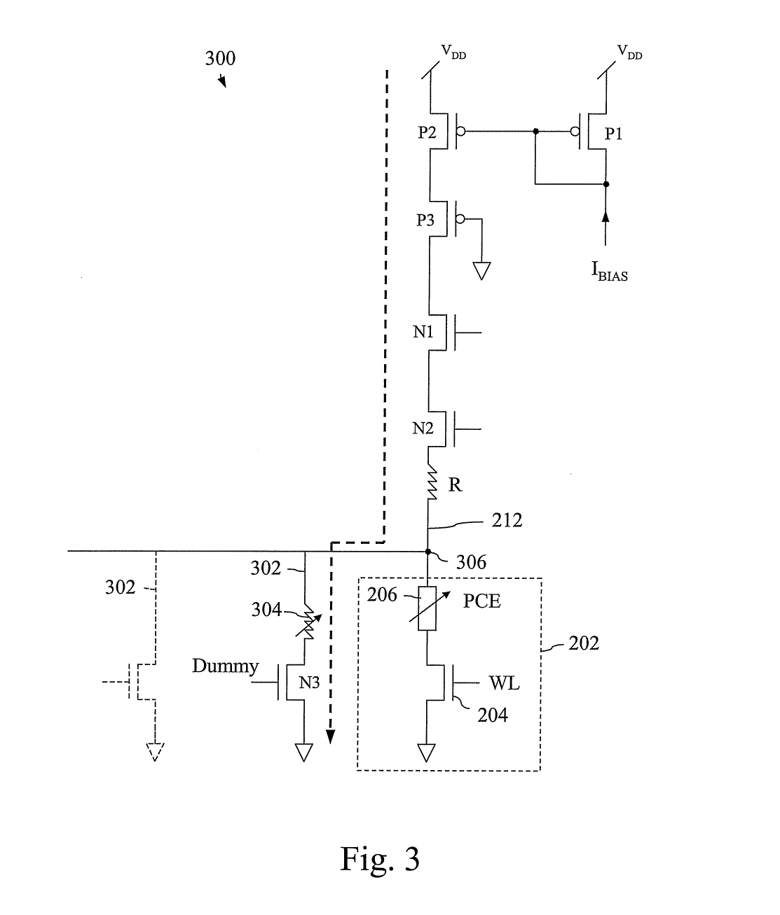

Accordingly, FIG. 3 is a schematic diagram of a bit line precharging device 300 configured to provide a dummy path 302 for current mode precharging, in accordance with an embodiment of the invention. The write control system depicted therein will deliver a prescribed total power over a given period of time independent of array location and process variations.

More specifically, a current mode write source includes PFET devices P1, P2 and P3 configured as a current mirror for input current I_{BIAS}, with PFETs P2 and P3 connected as a cascode amplifier in the bit line 212 path. As further depicted in FIG. 3, the bit line 212 includes access transistors N1 and N2 (e.g., included within the bit line control circuitry 214 of FIG. 2), and a parasitic resistance of the bit line 212 is depicted as “R.” During a precharge mode, a dummy path 302 is used to short circuit the phase change cell 202 when a control signal “Dummy” is applied to dummy access transistor N3. The dummy path may optionally include a tunable resistor 304 in series with the dummy access transistor N3, which may have the same or a different resistance value than the regular PCE's on resistance. In lieu of resistor 304, the dummy path resistance could also be tuned by adjusting the voltage applied to the gate of N3. In addition, although the dummy access transistor N3 is depicted at the same end of the bit line as the cell 202, it may also be located at the beginning, end, middle or even multiple positions on the bit line 212.

The dummy path 302 allows for two time dependent variables to approach their final operating point before opening up the PCE device 206 to power delivery. First, the current flow (dashed arrow) from the driver (P1, P2, P3) and through the bit line system achieves a DC operating point; second, the bit line voltage charged up across the bit line at node 306 is allowed to reach its DC operating point based upon the dummy device current path. Both of these operating points can take some time to reach and would otherwise expose the cell 202 to unnecessary power, and have possibly negative effects on the reliability of the PCE devices 206.

Once the “dummy” operating point is reached, the dummy access transistor N3 is deactivated and the word line signal (WL) of the cell 202 is activated, thus rendering the cell's access transistor 204 conductive and beginning the heating process of the PCE 206 (e.g., “set” or “reset”). Once the state of the PCE is set to the low resistance crystalline sate or reset to the high resistance amorphous state, the write operation is then terminated by deactivating the word line access transistor 204 and operating and a discharge device (not shown) to rapidly remove the charge from the bit line 212.

Because the relatively large bit line capacitance is already precharged prior to activating the word line access transistor 204, there is no significant delay in the application of a steady state heating power to the cell. This is a significant advantage for high-speed write operations having pulse lengths shorter than 20 ns, wherein fluctuations of the time-temperature history by even a few nanoseconds can affect the final PCE resistance state.

In an exemplary embodiment, the control circuitry begins to charge the bit line path to a preset level through the dummy path 302. This may be done on multiple bit lines, and each bit line could optionally be precharged to a different levels. In addition, multiple current sources and/or multiple levels of reference currents are also contemplated. In order to provide device flexibility (e.g., where the phase change element resistance, R_{PCE}, is not known), several dummy devices 302 with different dimensions (i.e., device strengths) may be used as depicted by the dashed device 302 in FIG. 3. In each case, prior to activating a word line access transistor, the associated dummy device is activated to precharge the bit line system into a proper operation point.

In lieu of (or in addition to) discrete devices, the dummy path access devices can also be used to quench (discharge) the bit line. For example, a bit line address can be set up to the final bit line access transistor. A desired write level could be placed across one bit line transistor with a zero potential placed across the remaining bit line access transistors. A “WLon” or “preWL” signal may be used to activate the final stage of the bit line and allow the actual write to take place or just the set up phase, respectively (WL or “preWL”). A “WLoff” signal can be used to deactivate the word line access transistor and at the same time activate the dummy access device to quench the bit line.

The idea of using a single signal to both shut the access device and quench the bit line leads to the question of timing and critical timing paths. In this regard, the dummy access transistor(s) may be located at various locations along the bit lines. Depending on whether the device is quenching or precharging before a write operation, it may be desired to turn the dummy access transistor “on” or “off” fractions of a nanosecond before the actual word line transistor is activated/deactivated. If the on/off signals originate from one side of the array, there is an opportunity to build the desired signal skew into the design.

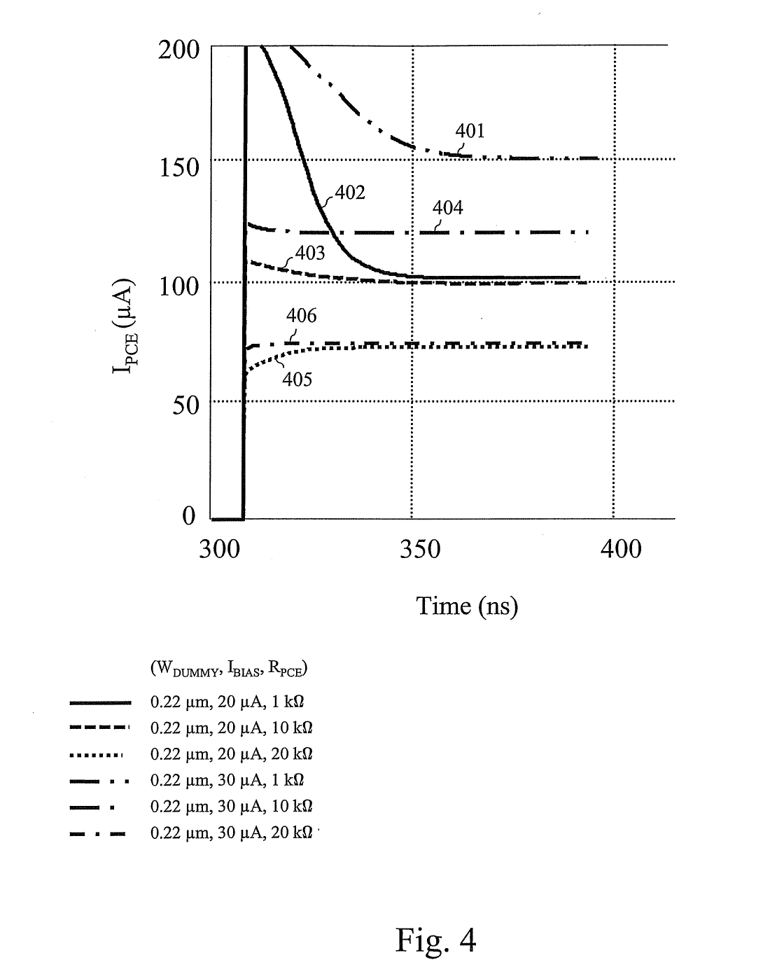

FIG. 4 is a graph illustrating various precharging current curves for various dummy path resistance values and bias current values. As reflected by curve 401, there is a significant overshoot of current (I_{PCE}) applied through a phase change element having a resistance of 10 kΩ, when the bit line is precharged with a bias current of 30 μA through a 0.22 μm dummy access transistor that has a resistance path of 1 kΩ. In this case, the generated precharge condition is not ideally matched with the memory cell. Decreasing the bias current to 20 μA as shown in curve 402 decreases the overshoot time for a 10 kΩ PCE, but the bias conditions are still not ideal.

In contrast, bias currents of 20 μA and 30 μA are better suited for a 10 kΩ dummy path resistance, as reflected by curves 403 and 404, respectively. As the dummy path resistance is further increased to 20 kΩ, an undershoot of the PCE current is initially seen for 20 μA and 30 μA bias currents, as reflected in curves 405 and 406. Thus, depending upon the selected value of I_{BIAS}, the resistance of the dummy path, and the value of R_{PCE}, the precharge conditions can be tailored for optimal matching with the operating point of the memory cell, thus improving performance from a power and speed perspective.

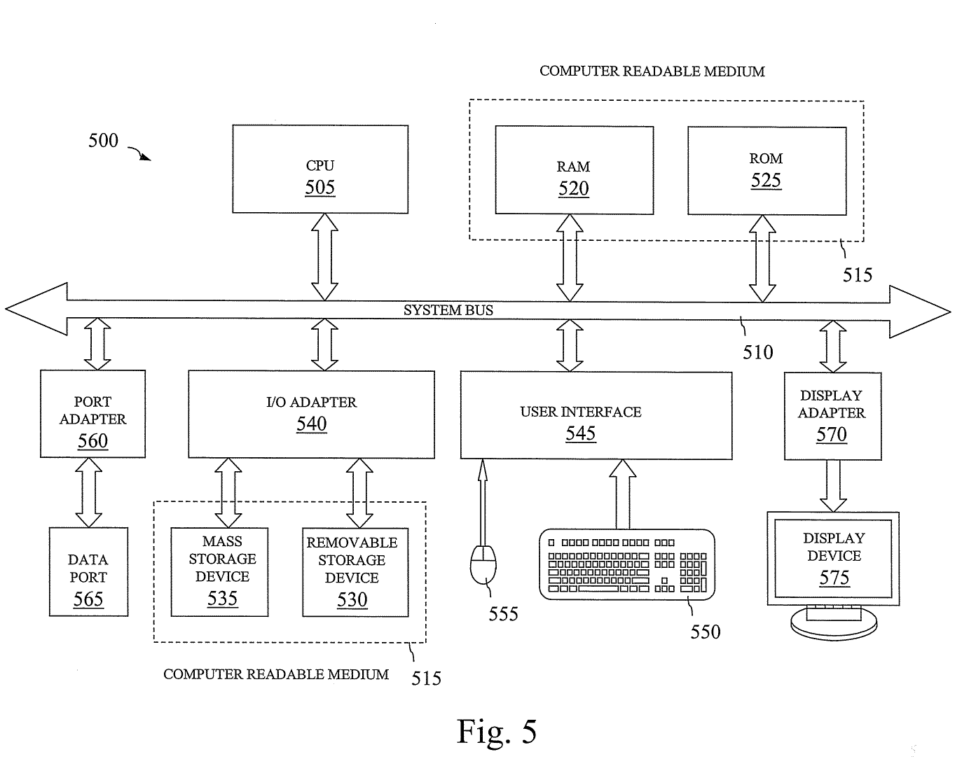

FIG. 5 illustrates a block diagram of an exemplary general-purpose computer system 500 which can be used to implement the circuit and circuit design structure embodiments described herein. The design structure may be coded as a set of instructions on removable or hard media for use by general-purpose computer. The computer system of FIG. 5 includes at least one microprocessor or central processing unit (CPU) 505, which is interconnected via a system bus 510 to machine readable media 515, which includes, for example, a random access memory (RAM) 520, a read-only memory (ROM) 525, a removable and/or program storage device 530 and a mass data and/or program storage device 535. An input/output (1/0) adapter 540 connects mass storage device 535 and removable storage device 530 to system bus 510. A user interface 545 connects a keyboard 550 and a mouse 555 to system bus 510, and a port adapter 560 connects a data port 565 to system bus 510. Further, a display adapter 570 connects a display device 575 to the system bus 510. ROM 525 contains the basic operating system for computer system 500.

Examples of removable data and/or program storage device 530 include magnetic media such as floppy drives, tape drives, portable flash drives, zip drives, and optical media such as CD ROM or DVD drives. Examples of mass data and/or program storage device 535 include hard disk drives and non-volatile memory such as flash memory. In addition to keyboard 550 and mouse 555, other user input devices such as trackballs, writing tablets, pressure pads, microphones, light pens and position-sensing screen displays may be connected to user interface 545. Examples of display device 575 include cathode-ray tubes (CRT) and liquid crystal displays (LCD).

A machine readable computer program may be created by one of skill in the art and stored in computer system 500 or a data and/or any one or more of machine readable medium 515 to simplify the practicing of the invention embodiments. In operation, information for the computer program created to run the present invention is loaded on the appropriate removable data and/or program storage device 530, fed through data port 565 or entered using keyboard 550. A user controls the program by manipulating functions performed by the computer program and providing other data inputs via any of the above mentioned data input means. Display device 575 provides a means for the user to accurately control the computer program and perform the desired tasks described herein.

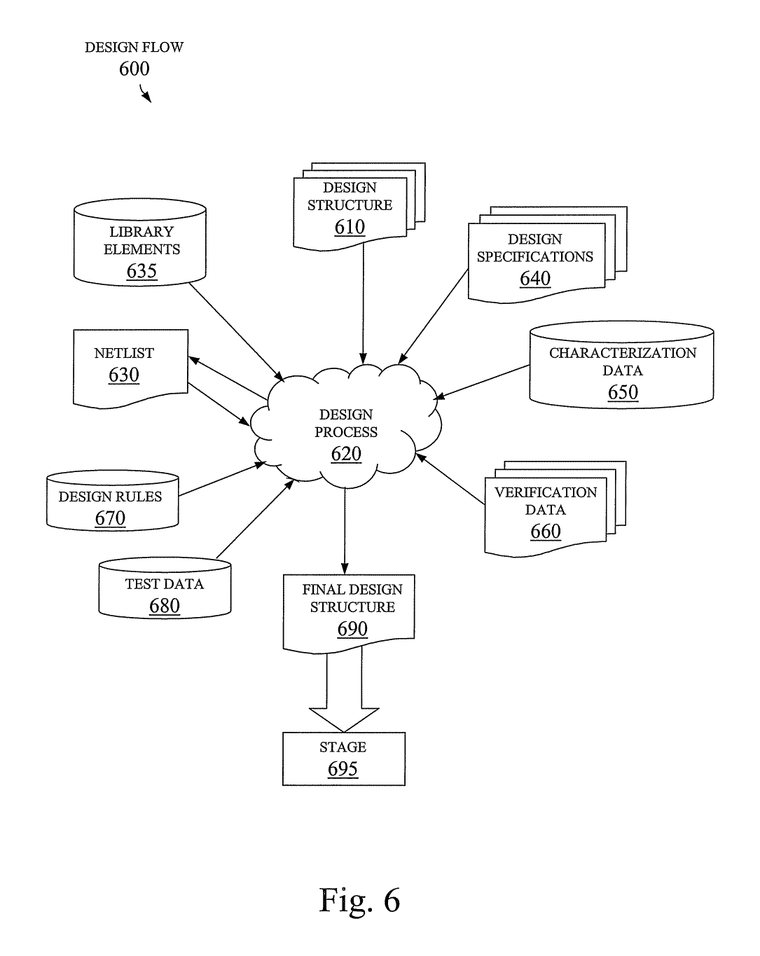

FIG. 6 is a block diagram illustrating an example of a design flow 600. Design flow 600 may vary depending on the type of IC being designed. For example, a design flow 600 for building an application specific IC (ASIC) will differ from a design flow 600 for designing a standard component. Design structure 610 is an input to a design process 620 and may come from an intellectual property (IP) provider, a core developer, or other design company. Design structure 610 comprises circuit embodiments 200, 300 in the form of schematics or HDL, a hardware-description language, (e.g., Verilog, VHDL, C, etc.). Design structure 610 may be on one or more of machine readable medium 515 as shown in FIG. 5. For example, design structure 610 may be a text file or a graphical representation of circuit embodiments 200, 300. Design process 720 synthesizes (or translates) circuit embodiments 200, 300 into a netlist 630, where netlist 630 is, for example, a list of wires, transistors, logic gates, control circuits, I/O, models, etc., and describes the connections to other elements and circuits in an integrated circuit design and recorded on at least one of machine readable medium 515.

Design process 620 includes using a variety of inputs; for example, inputs from library elements 635 which may house a set of commonly used elements, circuits, and devices, including models, layouts, and symbolic representations, for a given manufacturing technology (e.g., different technology nodes, 32 nm, 45 nm, 90 nm, etc.), design specifications 640, characterization data 650, verification data 660, design rules 670, and test data files 680, which may include test patterns and other testing information. Design process 620 further includes, for example, standard circuit design processes such as timing analysis, verification tools, design rule checkers, place and route tools, etc. One of ordinary skill in the art of integrated circuit design can appreciate the extent of possible electronic design automation tools and applications used in design process 620 without deviating from the scope and spirit of the invention.

Ultimately, design process 620 translates circuit embodiments 200, 300, along with the rest of the integrated circuit design (if applicable), into a final design structure 690 (e.g., information stored in a GDS storage medium). Final design structure 690 may comprise information such as, for example, test data files, design content files, manufacturing data, layout parameters, wires, levels of metal, vias, shapes, test data, data for routing through the manufacturing line, and any other data required by a semiconductor manufacturer to produce circuit embodiments 200, 300. Final design structure 690 may then proceed to a stage 695 of design flow 600, where stage 695 is (for example) where final design structure 690: proceeds to tape-out, is released to manufacturing, is sent to another design house or is sent back to the customer.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A design structure embodied in a machine readable medium used in a design process, the design structure comprising:
a circuit for implementing a write operation for a programmable resistive random access memory array, the circuit including a current source coupled to a bit line associated with a programmable resistive memory element;
a dummy path configured for selective coupling to the bit line prior to activation of a word line associated with the memory element, wherein the passage of current through the bit line and dummy path precharges the bit line; and
control circuitry for decoupling the dummy path from the bit line and for activating the word line associated with the memory element upon achieving a desired operating point of bit line current and bit line voltage, so as to cause current from the bit line to flow for a period of time selected to program the memory element to one of a low resistance state and a high resistance state.

2. The design structure of claim 1, wherein the programmable resistive memory element comprises a phase change element (PCE), with the low resistance state corresponding to a crystalline state and the high resistance state corresponding to an amorphous state.

3. The design structure of claim 2, further comprising a dummy access transistor configured to couple the dummy path to the bit line through a control signal applied thereto.

4. The design structure of claim 3, further comprising a quenching device for quenching the bit line following the period of time selected to program the memory element to one of a low resistance crystalline state and a high resistance amorphous state by discharging any remaining charge on the bit line.

5. The design structure of claim 4, wherein the quenching device for quenching the bit line comprises the dummy access transistor.

6. The design structure of claim 2, wherein a word line control signal is used for both activating a word line access transistor associated with the memory element and deactivating the dummy access transistor.

7. The design structure of claim 2, wherein the dummy path is configured to have a tunable resistance value.

8. The design structure of claim 1, wherein the design structure comprises a netlist describing the circuit for implementing a write operation for a programmable resistive random access memory array.

9. The design structure of claim 1, wherein the design structure resides on a GDS storage medium.

10. The design structure of claim 1, wherein the design structure includes test data files, characterization data, verification data, programming data, or design specifications.

11. A design structure embodied in a machine readable medium used in a design process, the design structure comprising:
a phase change random access memory (PCRAM) array, the array including a plurality of memory cells arranged into rows and columns, each of the memory cells including a phase change element (PCE) and an access transistor associated therewith;
a plurality of word lines, with each access transistor coupled to one of the word lines;
a plurality of bit lines, with each access transistor configured to electrically couple its associated PCE to one of the bit lines upon word line activation;
one or more current sources selectively coupled to the plurality of bit lines;
a dummy path associated with each bit line, each dummy path configured for selective coupling to the bit line in a precharging operation prior passage of current through any of the PCEs associated with the bit line; and
control circuitry for decoupling each dummy path from the associated bit line and for activating the word line associated with the PCE upon achieving a desired operating point of bit line current and bit line voltage, so as to cause current from the bit line to flow through the PCE for a period of time selected to program the PCE to one of a low resistance crystalline state and a high resistance amorphous state.

12. The design structure of claim 11, wherein the array further comprises a dummy access transistor configured to couple each dummy path to the associated bit line through a control signal applied thereto.

13. The design structure of claim 12, wherein the array further comprises a quenching device for quenching each bit line following the period of time selected to program the associated PCE to one of a low resistance crystalline state and a high resistance amorphous state by discharging any remaining charge on the bit line.

14. The design structure of claim 13, wherein the quenching device for quenching the bit line comprises the dummy access transistor.

15. The design structure of claim 12, wherein a word line control signal is used for both activating the word line access transistor associated with the PCE and deactivating the dummy access transistor.

16. The design structure of claim 11, wherein the dummy path is configured to have a tunable resistance value.

17. The design structure of claim 11, wherein the design structure comprises a netlist describing the circuit for implementing the PCRAM array.

18. The design structure of claim 11, wherein the design structure resides on a GDS storage medium.

19. The design structure of claim 11, wherein the design structure includes test data files, characterization data, verification data, programming data, or design specifications.
